(19) United States
(12) Patent Application Publication
(10) Pub. No.: US 2011/0147704 A1
(43) Pub. Date: Jun. 23, 2011

(54) SEMICONDUCTOR LIGHT-EMITTING DEVICE WITH PASSIVATION LAYER

(75) Inventors: Fengyi Jiang, Jiangxi (CN); Junlin Liu, Jiangxi (CN); Li Wang, Jiangxi (CN)

(73) Assignee: LATTICE POWER (JIANGXI) CORPORATION, Nanchang, Jiangxi (CN)

(21) Appl. No.: 13/059,398

(22) PCT Filed: Aug. 19, 2008
(86) PCT No.: PCT/CN08/01491

§ 371 Date: Feb. 16, 2011

(30) Foreign Application Priority Data
Aug. 19, 2008 (CN) PCT/CN2008/001491

(51) Int. Cl. H01L 33/04; H01L 33/44; B82Y 99/00

(52) U.S. Cl. 257/13; 438/38; 257/E33.008; 257/E33.06; 977/759; 977/949

(57) ABSTRACT

A light-emitting device and method for the fabrication thereof. The device includes a substrate, a first doped semiconductor layer situated above the substrate, a second doped semiconductor layer situated above the first doped semiconductor layer, and a multi-quantum-well (MQW) situated between the first and the second doped semiconductor layer. The device also includes a first electrode coupled to the first doped semiconductor layer and a second electrode coupled to the second doped semiconductor layer. The device further includes a first passivation layer which substantially covers the sidewalls of the first and second doped semiconductor layers, the MQW active layer, and the part of the horizontal surface of the second doped semiconductor layer which is not covered by the second electrode. The first passivation layer is formed through an oxidation technique. The device further includes a second passivation layer overlaying the first passivation layer.

### BACKGROUND

1. Field of the Invention

The present invention relates to the design of semiconductor light-emitting devices. More specifically, the present invention relates to novel semiconductor light-emitting devices with two layers of passivation that can effectively reduce the leakage current and enhance the device reliability.

2. Related Art

Solid-state lighting is expected to bring the next wave of illumination technology. High-brightness light-emitting diodes (HB-LEDs) are emerging in an increasing number of applications, from serving as the light source for display devices to replacing light bulbs for conventional lighting. Typically, cost, efficiency, and brightness are the three foremost metrics for determining the commercial viability of LEDs.

An LED produces light from an active region which is “sandwiched” between a positively doped layer (p-type doped layer) and a negatively doped layer (n-type doped layer). When the LED is forward-biased, the carriers, which include holes from the p-type doped layer and electrons from the n-type doped layer, recombine in the active region. In direct band-gap materials, this recombination process releases energy in the form of photons, or light, whose wavelength corresponds to the band-gap energy of the material in the active region.

To ensure high efficiency of an LED, it is desirable to have the carriers recombine only in the active region instead of in other areas such as on the lateral surface of the LED. However, due to the abrupt termination of the crystal structure at the surfaces of the LED, there can be large numbers of recombination centers on those surfaces. In addition, the energy band gap often shrinks at the surface resulting in an increase in leakage current at the edge of the device.

The surface of an LED is also very sensitive to its surrounding environment, which may lead to added impurities and defects. Environmentally induced damage can severely degrade the reliability and stability of an LED. In order to insulate an LED from various environmental factors, such as humidity, ion impurity, external electrical field, heat, etc., and to maintain the functionality and stability of the LED, it is important to maintain the surface cleanness and to ensure reliable LED packaging. Moreover, it is also critical to protect the surface of the LED using surface passivation, which typically involves depositing a thin layer of non-reactive material on the surface of the LED.

### SUMMARY

One embodiment of the present invention provides a light-emitting device. The device includes a substrate, a first doped semiconductor layer situated above the substrate, a second doped semiconductor layer situated above the first doped semiconductor layer, and a multi-quantum-well (MQW) active layer situated between the first and the second doped semiconductor layers. The device also includes a first electrode coupled to the first doped semiconductor layer and a second electrode coupled to the second doped semiconductor layer. The device further includes a first passivation layer which substantially covers the sidewalls of the first and second doped semiconductor layers, the MQW active layer, and part of the horizontal surface of the second doped semiconductor layer which is not covered by the second electrode. The first passivation layer is formed using an oxidation technique. The device further includes a second passivation layer overlaying the first passivation layer.

In a variation on this embodiment, the substrate comprises at least one of the following materials: Cu, Cr, Si, and SiC.

In a variation on this embodiment, the first passivation layer comprises Ga₂O₃.

In a variation on this embodiment, the second passivation layer comprises at least one of the following materials: SiOₓ, SiNₓ, or SiOₓN_{y}.

In a variation on this embodiment, the first doped semiconductor layer is a p-type doped semiconductor layer.

In a variation on this embodiment, the second doped semiconductor layer is an n-type doped semiconductor layer.

In a variation on this embodiment, the MQW active layer comprises GaN and InGaN.

In a variation on this embodiment, the first and second doped semiconductor layers are grown on a substrate with a predefined pattern comprising grooves and mesas.

In a variation on this embodiment, the first passivation layer is formed by applying oxygen plasma.

In a variation on this embodiment, the second passivation layer is formed by one of the following processes: plasma-enhanced chemical vapor deposition (PECVD), magnetron sputtering deposition, and electron beam (e-beam) evaporation.

In a variation on this embodiment, the thickness of the first passivation layer is between 1 and 100 nanometers, and the thickness of the second passivation layer is between 30 and 1,000 nanometers.

### BRIEF DESCRIPTION OF THE FIGURES

FIG. 1 illustrates a traditional passivation method for an LED with a vertical-electrode configuration.

FIG. 2A illustrates part of a substrate with pre-patterned grooves and mesas in accordance with one embodiment of the present invention.

FIG. 2B illustrates the cross-section of a pre-patterned substrate in accordance with one embodiment of the present invention.

FIG. 3 presents a diagram illustrating the process of fabricating a light-emitting device with two passivation layers in accordance with one embodiment of the present invention.

### DETAILED DESCRIPTION

The following description is presented to enable any person skilled in the art to make and use the invention, and is provided in the context of a particular application and its requirements. Various modifications to the disclosed embodiments will be readily apparent to those skilled in the art, and the general principles defined herein may be applied to other embodiments and applications without departing from the spirit and scope of the present invention. Thus, the present invention is not limited to the embodiments shown, but is to be accorded the widest scope consistent with the claims.

### Overview

The recent developments in LED fabrication technology enable the use of GaN-based III-V compound semiconductors as materials for short-wavelength LED. These GaN-based LEDs have extended the LED emission spectrum to the green, blue, and ultraviolet regions. Note that in the following discussion, a “GaN material” can generally include an InₓGa_{y}Al_{1-x-y}N (0≦x≦1, 0≦y≦1) based compound, which can be a binary, ternary, or quaternary compound, such as GaN, InGaN, GaAlN, and InGaAlN.

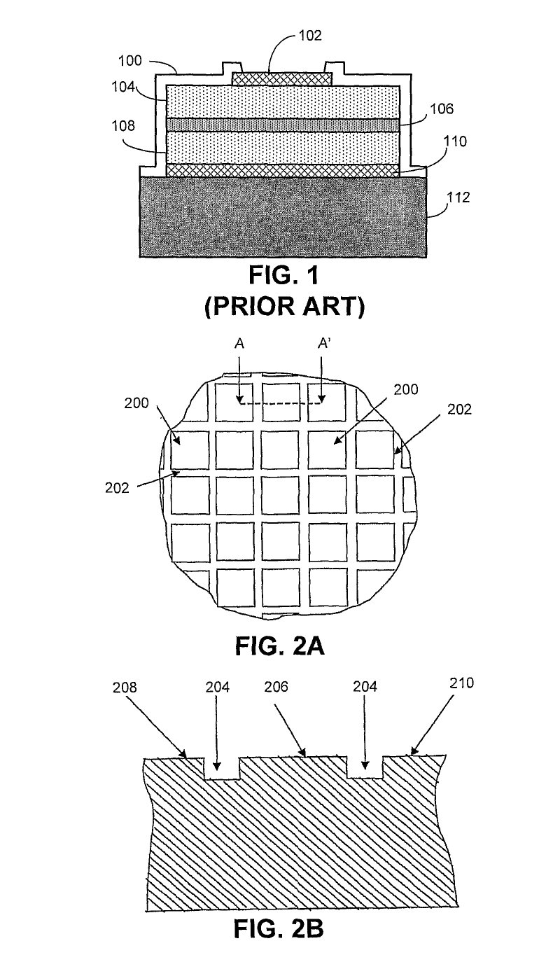

FIG. 1 illustrates a traditional passivation method for an LED with a vertical-electrode configuration, which includes a passivation layer 100, an n-side (or p-side) electrode 102, an n-type (or p-type) doped semiconductor layer 104, a active layer 106 based on a multi-quantum-well (MQW) structure, a p-type (or n-type) doped semiconductor layer 108, a p-side (or n-side) electrode 110, and a substrate 112.

The passivation layer blocks the undesired carrier recombination at the LED surface. For the vertical-electrode LED structure shown in FIG. 1, surface recombination tends to occur on the sidewalls of the MQW active region 106. However, sidewall coverage by a conventional passivation layer, for example, layer 100 shown in FIG. 1, is often non-ideal. The poor sidewall coverage is typically a result of standard thin-film deposition techniques, such as plasma-enhanced chemical vapor deposition (PECVD) and magnetron sputtering deposition. The quality of the sidewall coverage by the passivation layer is worse in devices with steeper steps, such as steps higher than 2 μm, which is the case for most vertical-electrode LEDs. Under such conditions, the passivation layer often contains a large number of pores, which can severely degrade its ability to block the surface recombination of carriers. An increased surface recombination rate in turn increases the amount of the reverse leakage current, which results in reduced efficiency and stability of the LED.

Embodiments of the present invention provide a method for fabricating a GaN based LED device with two layers of passivation. Two layers of passivation can effectively reduce the leakage current, resulting in improved reliability of the LED device. In one embodiment, instead of depositing only a single layer of passivation at the outer surface of the LED, two passivation layers (a first passivation layer, which comprises a thin layer of Ga₂O₃, and a second passivation layer, which can be a conventional passivation layer) are deposited. The presence of the first Ga₂O₃ passivation layer widens the energy band gap at the GaN surface, thus effectively blocking leakage current.

### Preparing Substrate

In order to grow a crack-free multilayer InGaAlN structure on a conventional large-area substrate (such as a Si wafer) to facilitate the mass production of high-quality, low-cost, short-wavelength LEDs, a growth method that pre-patterns the substrate with grooves and mesas is introduced. Pre-patterning the substrate with grooves and mesas can effectively release the stress in the multilayer structure that is caused by lattice-constant and thermal-expansion-coefficient mismatches between the substrate surface and the multilayer structure.

FIG. 2A illustrates a top view of a part of a substrate with a pre-etched pattern using photo lithographic and plasma-etching techniques in accordance with one embodiment of the present invention. Square mesas 200 and grooves 202 are the result of the etching. FIG. 2B more clearly illustrates the structure of mesas and grooves by showing a cross section of the pre-patterned substrate along a horizontal line AA′ in FIG. 2A in accordance with one embodiment. As seen in FIG. 2B, the sidewalls of grooves 204 effectively form the sidewalls of the isolated mesa structures, such as mesa 206, and partial mesas 208 and 210. Each mesa defines an independent surface area for growing a respective semiconductor device.

Note that it is possible to apply different lithographic and etching techniques to form the grooves and mesas on the semiconductor substrate. Also note that other than forming square mesas 200 as shown in FIG. 2A, alternative geometries can be formed by changing the patterns of grooves 202. Some of these alternative geometries can include, but are not limited to: triangle, rectangle, parallelogram, hexagon, circle, or other non-regular shapes.

Fabricating Light-Emitting Device with Two Passivation Layers

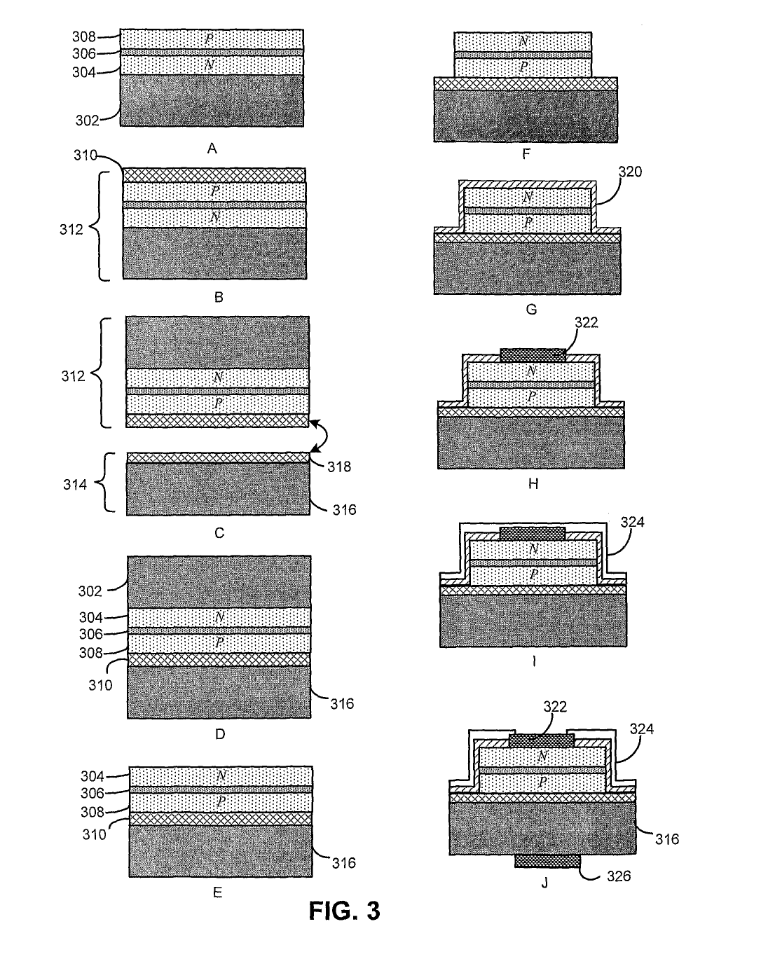

FIG. 3 presents a diagram illustrating the process of fabricating a light-emitting device with two layers of passivation in accordance with one embodiment of the present invention. In operation A, after a pre-patterned substrate with grooves and mesas is prepared, an InGaAlN multilayer structure can be formed using various growth techniques, which can include but are not limited to Metalorganic Chemical Vapor Deposition (MOCVD). The fabricated LED structure can include a substrate 302, which can be a Si wafer; an n-type doped semiconductor layer 304, which can be a Si doped GaN layer; an active layer 306, which can be a GaN/InGaAlN MQW structure; and a p-type doped semiconductor layer 308, which can be an Mg doped GaN layer. Note that it is possible to reverse the sequence of the growth between the p-type layer and n-type layer.

In operation B, a metal layer 310 is deposited above the multilayer structure 312 to form an ohmic contact. If metal layer 310 is coupled with a p-type doped material, then metal layer 310 is a p-side ohmic-contact metal layer. P-side ohmic contact layer 310 may include several types of metal, such as nickel (Ni), gold (Au), platinum (Pt), and an alloy thereof. P-side ohmic-contact metal layer 310 can be deposited using an evaporation technique such as electro-beam (e-beam) evaporation.

In operation C, multilayer structure 312 is flipped upside down to bond with a supporting conductive structure 314. Note that, in one embodiment, supporting conductive structure 314 includes a supporting substrate 316 and a bonding layer 318. In addition, a layer of bonding metal can be deposited on p-side ohmic-contact metal layer 310 to facilitate the bonding process. Supporting substrate layer 316 is conductive and may include silicon (Si), copper (Cu), silicon carbide (SiC), chromium (Cr), and other materials. Bonding layer 318 may include gold (Au). FIG. 3D illustrates the cross section of the multilayer structure after bonding.

After bonding, in operation E, substrate 302 is removed. Techniques that can be used for the removal of the substrate layer 302 can include, but are not limited to: mechanical grinding, dry etching, chemical etching, and any combination of the above methods. In one embodiment, the removal of substrate 302 is completed by employing a chemical-etching process, which involves submerging the multilayer structure in a solution based on hydrofluoric acid, nitric acid, and acetic acid, Note that supporting substrate layer 316 can be optionally protected from this chemical etching.

In operation F, the edge of the multilayer structure is removed to reduce surface recombination centers and ensure high material quality throughout the entire device. However, if the growth procedure can guarantee a good edge quality of the multilayer structure, then this edge removal operation can be optional.

In operation G, a first passivation layer 320 is formed covering the top surface and the sidewalls of the multilayer structure. In one embodiment, the first passivation layer can comprise Ga₂O₃ and is formed using an oxidation technique. For example, oxygen plasma can be applied to oxidize the GaN material to form the first passivation layer. Because first passivation layer 322 is formed by chemical reaction, the number of dangling bonds can be significantly reduced at the interface due to the strong chemical bonds formed in the oxidization. Also, because the band gap of the Ga₂O₃ material is approximately 5 ev, wider than that of the GaN material, which is around 3.5 ev, the thin layer of the Ga₂O₃ material at the GaN surface will cause the band gap to widen at the GaN surface. Therefore, the formation of the first passivation layer can effectively reduce the leakage current. The thickness of the first passivation layer is between several nanometers and several tens of nanometers.

In operation H, after photolithographic patterning and etching are applied to first passivation layer 320, an ohmic electrode 322 is formed on the exposed area of the n-type doped semiconductor layer. The material composition and formation process of n-side ohmic electrode 322 is similar to that of p-side ohmic-contact metal layer 310.

In operation I, a second passivation layer 324 is deposited covering the top surface and sidewalls of the multilayer surface. Materials that can be used to form second passivation layer 324 include, but are not limited to: silicon oxide (SAN), silicon nitride (SiNₓ), and silicon oxynitride (SiOₓN_{y}). Various thin-film deposition techniques, such as PECVD and magnetron sputtering deposition, can be used to deposit second passivation layer 324. The thickness of the second passivation layer is between 30 and 1,000 nanometers. In one embodiment of the present invention, the second passivation layer is approximately 200 nanometers thick.

In operation J, photolithographic patterning and etching are applied to second passivation layer 324 to expose n-side ohmic electrode 322, and a p-side electrode 326 is formed on the backside of supporting substrate layer 316.

The foregoing descriptions of embodiments of the present invention have been presented only for purposes of illustration and description. They are not intended to be exhaustive or to limit the present invention to the forms disclosed. Accordingly, many modifications and variations will be apparent to practitioners skilled in the art. Additionally, the above disclosure is not intended to limit the present invention. The scope of the present invention is defined by the appended claims.

What is claimed is:

1. A semiconductor light-emitting device, comprising:
a substrate;
a first doped semiconductor layer situated above the substrate;
a second doped semiconductor layer situated above the first doped semiconductor layer;
a multi-quantum-well (MQW) active layer situated between the first and the second doped semiconductor layers; and
a first electrode coupled to the first doped semiconductor layer;
a second electrode coupled to the second doped semiconductor layer;
a first passivation layer which substantially covers the sidewalls of the first and second doped semiconductor layers, the MQW active layer, and part of the horizontal surface of the second doped semiconductor layer which is not covered by the second electrode, wherein the first passivation layer is formed using an oxidation technique; and
a second passivation layer overlaying the first passivation layer.

2. The semiconductor light-emitting device of claim 1,
wherein the substrate comprises at least one of the following materials:
Cu,
Cr,
Si, and
SiC.

3. The semiconductor light-emitting device of claim 1,
wherein the first passivation layer comprises Ga₂O₃.

4. The semiconductor light-emitting device of claim 1,
wherein the second passivation layer comprises at least one of the following materials:
silicon oxide (SiOₓ),
silicon nitride (SiN_{x,}), and
silicon oxynitride (SiOₓN_{y}).

5. The semiconductor light-emitting device of claim 1,
wherein the first doped semiconductor layer is a p-type doped semiconductor layer.

6. The semiconductor light-emitting device of claim 1,
wherein the second doped semiconductor layer is an n-type doped semiconductor layer.

7. The semiconductor light-emitting device of claim 1,
wherein the MQW active layer comprises GaN and InGaN.

8. The semiconductor light-emitting device of claim 1,
wherein the first and second doped semiconductor layers are grown on a substrate with a pre-defined pattern of grooves and mesas.

9. The semiconductor light-emitting device of claim 1,
wherein the first passivation layer is formed by applying oxygen plasma.

10. The semiconductor light-emitting device of claim 1,
wherein the second passivation layer is formed by at least one of the following processes:
plasma-enhanced chemical vapor deposition (PECVD),
magnetron sputtering deposition, or
electro-beam (e-beam) evaporation.

11. The semiconductor light-emitting device of claim 1,
wherein the thickness of the first passivation layer is between 1 and 100 nanometers, and wherein the thickness of the second passivation layer is between 30 and 1,000 nanometers.

12. A method for fabricating a semiconductor light-emitting device, the method comprising:
growing a multilayer semiconductor structure on a first substrate, wherein the multilayer semiconductor structure comprises a first doped semiconductor layer, an MQW active layer, and a second doped semiconductor layer;
forming a first electrode, which is coupled to the first doped semiconductor layer;
bonding the multilayer structure to a second substrate;
removing the first substrate;
forming a first passivation layer which substantially covers the top surface and the sidewalls of the multilayer structure, wherein the first passivation layer is formed using an oxidation technique;
forming a second electrode, which is coupled to the second doped semiconductor layer; and
forming a second passivation layer, which overlays the first passivation layer.

13. The method of claim 12,
wherein the second substrate comprises at least one of the following materials:
Cu,
Cr,
Si, and
SiC.

14. The method of claim 12,
wherein the first passivation layer comprises Ga₂O₃.

15. The method of claim 12,
wherein the second passivation layer comprises at least one of the following materials:
silicon oxide (SiOₓ),
silicon nitride (SiNₓ), and
silicon oxynitride (SiOₓN_{y}).

16. The method of claim 12,
wherein the first doped semiconductor layer is a p-type doped semiconductor layer.

17. The method of claim 12,
wherein the second doped semiconductor layer is an n-type doped semiconductor layer.

18. The method of claim 12,
wherein the MQW active layer comprises GaN and InGaN.

19. The method of claim 12,
wherein the multilayer semiconductor structure is grown on a substrate with a pre-defined pattern of grooves and mesas.

20. The method of claim 12,
wherein the first passivation layer is formed by applying oxygen plasma.

21. The method of claim 12,
wherein the second passivation layer is formed by one of the following processes:
plasma-enhanced chemical vapor deposition (PECVD),
magnetron sputtering deposition, and
e-beam deposition.

22. The method of claim 12,
wherein the thickness of the first passivation layer is between 1 and 100 nanometers, and wherein the thickness of the second passivation layer is between 30 and 1,000 nanometers.
